(19) United States
(12) Patent Application Publication
(10) Pub. No.: US 2024/0353749 A1
(43) Pub. Date: Oct. 24, 2024

(54) METHODS, SOFTWARE, AND SYSTEMS FOR DETERMINATION OF CONSTANT-WIDTH SUB-RESOLUTION ASSIST FEATURES

(71) Applicant: ASML NETHERLANDS B.V., Veldhoven (NL)

(72) Inventors: Xingyue PENG, San Jose,, CA (US); Ningning JIA, Shenzhen (CN); Zhan SHI, San Jose, CA (US); Rafael C. HOWELL, Santa Clara, CA (US)

(73) Assignee: ASML NETHERLANDS B.V., Veldhoven (NL)

(21) Appl. No.: 18/713,143

(22) PCT Filed: Nov. 23, 2022
(86) PCT No.: PCT/EP2022/083060

§ 371 Date: May 23, 2024

(30) Foreign Application Priority Data
Dec. 14, 2021 (WO) PCT/CN2021/137860

(51) Int. Cl. G03F 1/36

(52) U.S. Cl. CPC G03F 1/36

(57) ABSTRACT

Methods, software, and systems are disclosed for determining mask patterns. The determination can include obtaining a mask pattern including sub-resolution assist features (SRAFs) each having constant widths. The widths are set as continuous variables and so can be optimized along with other variables during a mask optimization process of the mask pattern. Based on their population and/or statistics, the optimized continuous widths are then discretized to a limited number of global width levels. Further mask optimization be performed with the SRAFs having discretized optimized global width levels, where the width assigned to an individual SRAF may be adjusted to a different level of the global width levels.

### CROSS-REFERENCE TO RELATED APPLICATIONS

This application claims priority of International application PCT/CN2021/137860 which was filed on Dec. 14, 2021 and which is incorporated herein in its entirety by reference.

### TECHNICAL FIELD

The description herein relates generally to mask manufacturing and patterning processes. More particularly, the disclosure includes apparatus, methods, and computer programs for determining sub-resolution assist features.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”-generally the smallest feature size printed- and k1 is an empirical resolution factor. In general, the smaller kl the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

According to an embodiment, a method of determining mask patterns includes obtaining a mask pattern comprising sub-resolution assist features (SRAFs) each having constant widths; and adjusting the widths during a mask optimization process of the mask pattern.

In some embodiments, the method can also include accessing initial discrete width levels defined for the SRAFs; and assigning the widths to be initial widths from the initial discrete width levels. The method can include generating SRAF edges, where the SRAF edges can be generated to be at approximately equal distances from ridge points corresponding to a location of the SRAF. In some embodiments, the generated SRAF edges can be curved. Also, the ridge points can be determined such that the SRAF edges are smoothly varying. In some embodiments, ridge points can be determined from an SRAF Guidance Map (SGM), the ridge points located between the corresponding SRAF edges.

In some embodiments, generating of the SRAF edges can include performing interpolation over at least two ridge points when a distance between two ridge points exceeds a distance limit, the interpolation generating an interpolated ridge point. The interpolated ridge point can be generated at a midpoint of a segment between two ridge points. The interpolated ridge point can be generated along a spline interpolated curve between the two ridge points and the spline interpolated curve is generated utilizing at least one other ridge point.

The generating of the SRAF edges can include generating control points at both ends of segments normal to the ridge points of the SRAF. The segments can have a length corresponding to the constant width of the SRAF.

In some embodiments, the method can also include appending tips to the SRAF edges.

In some embodiments, the width of each SRAF can be set as a continuous variable that is optimized by the mask optimization process. The mask optimization process can include simulating a lithography process utilizing a lithography model; predicting an imaging characteristic of the mask as simulated by the lithography model; and adjusting the width of one or more SRAFs to optimize the imaging characteristic by use of a cost function related to the imaging characteristic.

In some embodiments, the mask optimization process can include performing optical proximity correction optimization to generate boundaries of mask features that include assist features (AFs) and can also include co-optimizing an illumination source in a source-mask optimization in a lithography system along with optimizing the mask features.

In some embodiments, a cost function utilized in the mask optimization process can include parameters describing one or more of an edge placement error, sidelobe printing, mask rule check (MRC) compliance, or a user-defined custom requirement, where at least one of the parameters is a function of the widths.

In some embodiments, the method can include determining selected widths for the SRAFs. The number of selected widths can be less than five.

In some embodiments, the method can include determining a population or population distribution of the optimized widths; setting the selected widths within a range of widths of the population or population distribution based on one or more rules; and setting the width of each SRAF to the nearest selected width. The rules can include setting the selected widths evenly within the range of widths.

In some embodiments, the width of each SRAF can be a discrete variable that can be optimized by the further mask optimization process, where there are fewer discrete variables than SRAFs. Each discrete variable can correspond to a global width level. The global width levels can be fixed during the mask optimization process or the global width levels can be optimized during the mask optimization process.

In some embodiments, adjusting of the widths can include determining continuous widths of the SRAFs as continuous variables; discretizing the continuous widths of the SRAFs into discrete widths; and continuing the mask optimization process by varying the widths to be selected from the discrete widths.

In some embodiments, there can be a non-transitory computer readable medium having instructions recorded thereon, the instructions when executed by a computer having at least one programmable processor cause operations comprising any of the operations in the above method embodiments.

In some embodiments, there can be a system for determining mask patterns, the system comprising: at least one programmable processor; and a non-transitory computer readable medium having instructions recorded thereon, the instructions when executed by a computer having the at least one programmable processor cause operations comprising any of the operations in the above method embodiments.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment of the present disclosure.

FIG. 2 illustrates an exemplary flow chart for simulating lithography in a lithographic projection apparatus, according to an embodiment of the present disclosure.

FIG. 3 illustrates an exemplary portion of a mask that contains main features (MFs) and sub-resolution assist features (SRAFs), according to an embodiment of the present disclosure.

FIG. 4 illustrates an exemplary constant width SRAF, according to an embodiment of the present disclosure.

FIG. 5 illustrates an exemplary method of determining mask patterns, according to an embodiment of the present disclosure.

FIG. 6 illustrates an exemplary method for generating SRAFs edges, according to an embodiment of the present disclosure.

FIG. 7 illustrates an exemplary method of discretizing SRAF widths, according to an embodiment of the present disclosure.

FIG. 8 illustrates a combined optimization method including optimizing widths as both continuous and discrete values in different parts of the optimization process, according to an embodiment of the present disclosure.

FIG. 9 is a block diagram of an example computer system, according to an embodiment of the present disclosure.

FIG. 10 is a schematic diagram of a lithographic projection apparatus, according to an embodiment of the present disclosure.

FIG. 11 is a schematic diagram of another lithographic projection apparatus, according to an embodiment.

FIG. 12 is a detailed view of the lithographic projection apparatus, according to an embodiment of the present disclosure.

FIG. 13 is a detailed view of the source collector module of the lithographic projection apparatus, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be interpreted as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

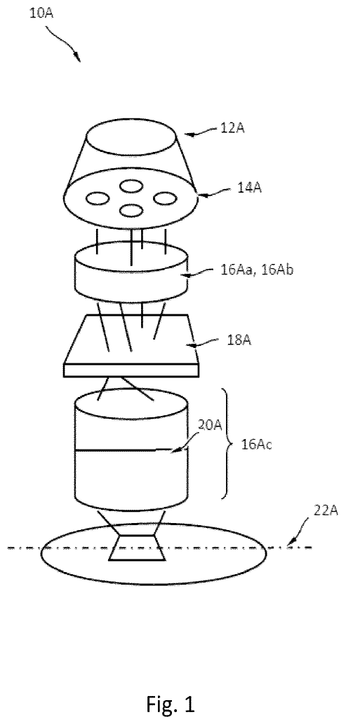

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

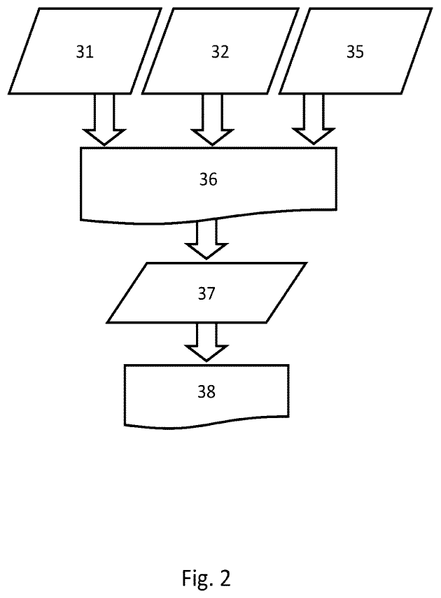

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (a) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$C F ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} )$$

where (z₁, z₂, . . . , z_{N}) are N design variables or values thereof. ƒₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with ƒₚ(z₁, z₂, . . . , z_{N}). For example, the characteristic may be a position of an edge of a pattern, measured at a given point on the edge. Different ƒₚ(z₁, z₂, . . . , z_{N}) may have different weight wₚ. For example, if a particular edge has a narrow range of permitted positions, the weight wₚ for the ƒₚ, (z₁, z₂, . . . , z_{N}) representing the difference between the actual position and the intended position of the edge may be given a higher value. ƒₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form as shown above. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, ƒₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” means a process that creates an etched substrate by the application of specified patterns of light as part of a lithography process.

As used herein, the term “target pattern” means an idealized pattern that is to be etched on a substrate.

As used herein, the term “printed pattern” means the physical pattern on a substrate that was etched based on a target pattern. The printed pattern can include, for example, troughs, channels, depressions, edges, or other two and three dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an imaging device model (e.g., that models what an imaging device may image from a printed pattern).

As used herein, the term “imaging device” means any number or combination of devices and associated computer hardware and software that can be configured to generate images of a target, such as the printed pattern or portions thereof. Non-limiting examples of an imaging devices can include: scanning electron microscopes (SEMs), x-ray machines, etc.

As used herein, the term “calibrating” means to modify (e.g., improve or tune) and/or validate something, such as the process model.

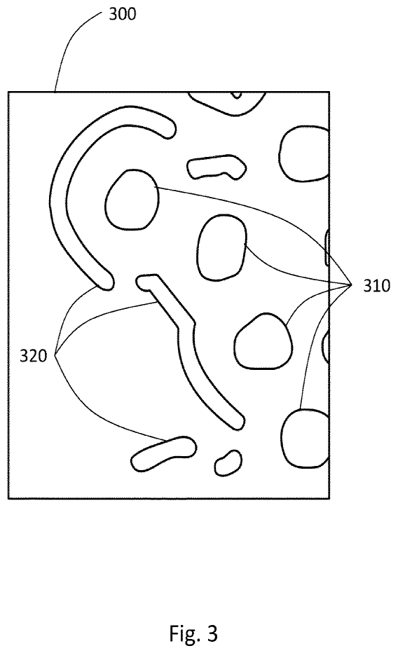

FIG. 3 illustrates an exemplary portion of a mask that contains main features (MFs) and sub-resolution assist features (SRAFs). The mask simulation/optimization processes described herein can be utilized to generate masks (or mask patterns) containing MFs that generally conform to desired features (e.g., circuit traces) to be printed utilizing the mask. FIG. 3 depicts an exemplary portion of a mask pattern 300 having a few simplified examples of MFs 310. Due to manufacturing limitations, diffraction effects, or other indirect or fine-scale effects, mask patterns may be generated to also include assist features (AFs) and/or SRAFs. AFs are not depicted in the example of FIG. 3 but are understood as being slight deviations to the shapes of the main features. Examples of such can be widening and/or narrowing, placing a notch in a corner of, etc. of main features in particular places to facilitate accurate printing with the mask. However, the present disclosure is primarily directed to determination of features relating to the SRAFs. As seen in FIG. 3, SRAFs 320 are mask features that are separate from the main (and assist) features and are further utilized on the mask to have the final printed pattern better approximate the target pattern. In general, SRAFs can vary in shape, including varying in the width along the SRAF. However, as described in greater detail herein, the present disclosure provides processes for determination and generation of SRAFs where each SRAF can have a constant width.

As used herein, the term “constant width” means that the width of an SRAF is substantially constant along its length, for example, varying by no more than 5%. Such variations in the final physical mask including the SRAFs can be due to manufacturing uncertainty. However, the calculated/simulated “constant width” SRAFs described herein may have similar small variations that may arise due to, for example, splines used to form the edges of the nominally “constant width” SRAFs.

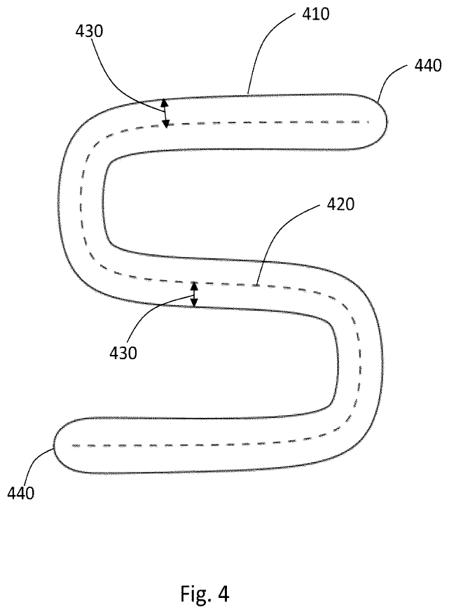

FIG. 4 illustrates an exemplary constant width SRAF. The shape of SRAFs that a mask optimization/generation process generates can be quite varied to correspond to the complex shapes required to optimize the simulated mask. Accordingly, the example depicted in FIG. 4 of the S-shaped SRAF 410 is exemplary and it is understood that any shape of the SRAF is considered within the scope of the present disclosure. In the embodiments as used herein, the general structure of an SRAF may be considered to have an SRAF “skeleton” with the SRAF in FIG. 4 having a skeleton 420 depicted by the dashed line at the center of the SRAF. The SRAF skeleton 420 thus represents generally where an SRAF should be in the mask pattern. SRAF locations can be determined with mask optimization processes that can include optimizing a continuous tone (greytone) image (sometimes referred to as an SRAF Guidance Map (SGM) or CTM) that indicates where SRAFs may be placed in order to improve the printing utilizing the resist made with the final mask. The SGM can have detectable variations that would appear as ridges which can thus indicate candidate SRAF locations.

In general, the width of an SRAFs can vary and, in some implementations, be part of an optimization process. However, the present disclosure describes processes for determining/optimizing widths of SRAFs where the width of each individual SRAF is constant. The example SRAF depicted in FIG. 4 is understood as having a constant width 430 (i.e., having substantially the same distance normal to either side of the SRAF skeleton). Also depicted are exemplary tips 440 of the SRAF that can be included to close the SRAF at an open end.

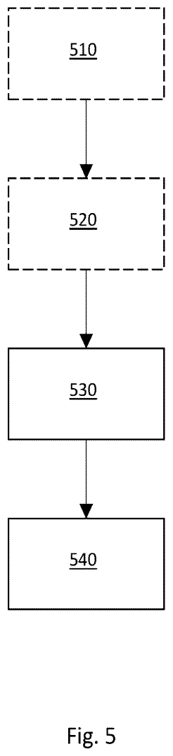

FIG. 5 illustrates an exemplary method of determining mask patterns. Optional initial method steps 510 and 520 are described below. In some embodiments, the method can include, at 530, obtaining a mask pattern having SRAFs each having constant widths. The method can also include, at 540, adjusting the widths during a mask optimization process of the mask pattern. For example, referring back to FIG. 3, while the depicted SRAFs appear to have the same width, the disclosed mask optimization process can vary/determine the constant widths of the individual SRAFs needed to best meet the printing requirements.

In some embodiments, the initial widths can be selected from a predetermined group of widths. For example, the method in FIG. 5 can include, at 510, accessing initial discrete width levels defined for the SRAFs. Then, at 520, the method can include assigning the widths to be initial widths from the initial discrete width levels.

Throughout the present disclosure, the terms “discrete” and “continuous” are used in relation to various embodiments to describe the width of an SRAF or a variable that represents width of an SRAF. As used herein, the term “discrete” refers to a number (e.g., a width) that can vary during an optimization process but selected from a finite number of available discrete widths. Examples of “discrete” widths can be 5 nm, 7 nm, 10 nm, etc. In contrast, the term “continuous” refers to a number/width that can be varied finely during an optimization process. Examples of “continuous” widths may, for example, range between 3-15 nm, with examples of changes through such ranges being from 5.0 nm, to 5.01 nm, to 5.000001 nm, or any other sort of infinitesimal change. The specific numeric values for widths given herein are considered to be examples only as the actual values are highly dependent with the particular implementation.

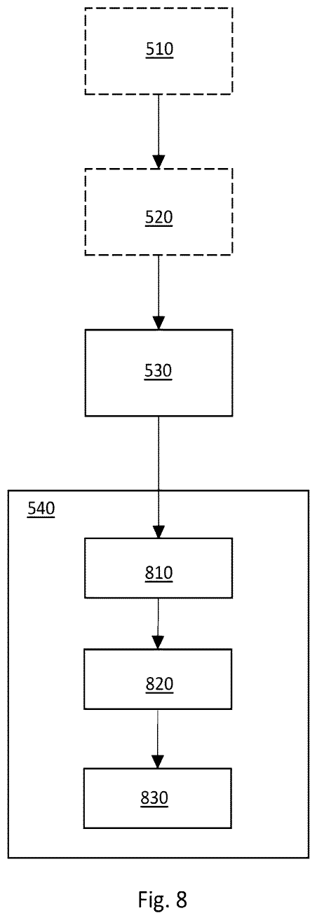

The initial widths can then be varied with by the mask optimization process. Depending on the implementation, the initial widths can remain discrete or may be treated as discrete or continuous depending on the particular implementation. For example, as discussed in greater detail below, FIG. 8 describes an embodiment where the mask optimization process can go from optimizing continuous widths to optimizing discrete widths.

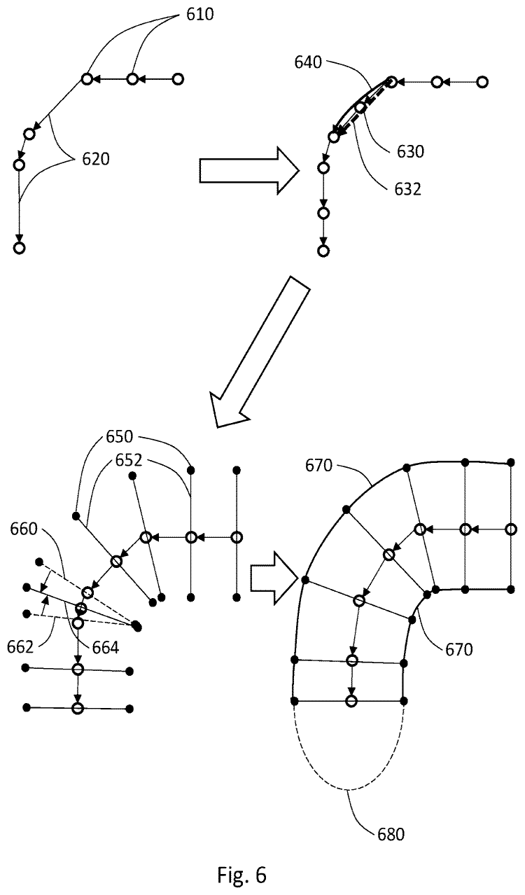

Before discussing how the widths of the SRAFs can be varied/optimized, embodiments relating to the generation of the actual SRAF edges are disclosed. Although embodiments are described in detail with reference to generating SRAFs using ridges, the present disclosure is not limited thereto. Any suitable method can be used without departing from the scope of the present disclosure. FIG. 6 illustrates an exemplary method for generating SRAFs edges. As previously discussed, candidate locations for an SRAF can be determined at particular locations on a mask pattern, such as at points corresponding to a ridge. The upper left portion of FIG. 6 depicts a number of points 610 that represent exemplary locations along the ridge and are herein referred to as “ridge points.” As shown through FIG. 6, the disclosed methods can include generating SRAF edges that may be generated at approximately equal distances from ridge points 610 corresponding to the skeleton of the SRAF. While the generated SRAF edges may be curved, (e.g., as shown in FIG. 3) in other embodiments they may be substantially linear or have varying sections that are linear or curved (e.g., as depicted in the example of FIG. 4). In some implementations, the ridge points can be determined such that the SRAF edges are smoothly varying. In some implementations, ridge points can be determined from the SGM in accordance with the prior discussion of the determination of SRAF locations. Accordingly, the ridge points can be located between the corresponding SRAF edges that will be further described with reference to the remainder of FIG. 6.

The upper right portion of FIG. 6 depicts an exemplary next step in an SRAF generation process. It can be seen in the upper left portion of the SRAF skeleton that near the center of the SRAF skeleton there are two segments 620 where the length of the segments (distance between the ridge points 610 corresponding to the endpoints) is substantially longer than the others in the SRAF skeleton. To provide a more uniform distribution of ridge points, generating the SRAF edges can include performing interpolation over at least two ridge points. This can occur, for example, when a distance between two ridge points exceeds a distance limit, the interpolation thereby generating an interpolated ridge point 630. The system can perform the interpolation when certain criteria are met, for example, an absolute distance between ridge points (e.g., greater than 5 nm, 10 nm, etc.), a relative distance between ridge points (e.g., more than 1.5× or more than 2.0× the mean separation between ridge points), or other criteria. In some embodiments, such as shown in the upper right of FIG. 6, linear interpolation can be utilized such that the interpolated ridge point 630 may be generated at a midpoint of a segment 632 between two ridge points, though in other implementations the interpolated ridge point can be at any location along the segment. In some embodiments, the interpolated ridge point can be generated along a spline interpolated curve 640 between the two ridge points. In some implementations, to have a more constrained and possibly more realistic curve, the spline interpolated curve can be generated utilizing at least one other ridge point. The upper right portion depicts an example of what a spline interpolated curve may look like although only the exemplary linearly interpolated ridge point is shown.

Continuing to the lower left portion of FIG. 6, in some embodiments, generating of the SRAF edges can include generating control points 650 at both ends of segments 652 normal to the ridge points of the SRAF. As used herein, the term “control points” refers to points along the eventual SRAF. As shown, the segments can have a length corresponding to the constant width of the SRAF. It is understood with the present disclosure that the depicted segments in FIG. 6 are largely for illustrative purposes only and that the computational algorithms that generate the SRAFs based on the ridge points need not literally calculate, generate, or display any of the described segments. For example, the depicted control points can merely be computed to be at the appropriate locations based on knowing the normal directions at the corresponding ridge point.

Also depicted in the lower left portion of FIG. 6 is an example where two of the segments (660, 662) would cross, thereby possibly creating artifacts or other irregularities in the resultant SRAFs if such points were used. In some embodiments, there can be a smoothing algorithm that can remove such irregularities. In this example, the two colliding segments are depicted as being collapsed into a single segment 664.

The lower right portion depicts generation of the SRAFs edges 670 based on the control points. As shown, the SRAFs edges can pass through the control points and may be generated by, for example, one or more splines through any number of the control points. As previously mentioned with regard to the definition of “constant width,” close inspection of the exemplary SRAFs edges shows that due to the particular features of the spline used to generate them (e.g., spline tension) the SRAFs width may not be exactly constant along the length of the SRAF. Thus, it is again understood that when the present disclosure refers to a constant width SRAF such is interpreted to include these sorts of minor variations. In some embodiments, generation of the SRAFs can include appending tips 680 to the SRAF edges, where appropriate. Such tips can be semicircular, semi-ellipsoidal, etc. In some embodiments, the tip can also be a direct closure (e.g., a line) between two control points at the end of the SRAF's edges.

As described with reference to the method of FIG. 5, certain embodiments of the present disclosure can include particular methods for optimizing the width of the SRAFs to obtain the best possible printing result. Depending on the implementation, the width may be treated as a continuous variable or a discrete variable.

In some embodiments, the width of each SRAF can be set as a continuous variable that is optimized by the mask optimization process. In this way, the mask optimization process can allow the width to vary at a very high precision or at a fine graduality in order to obtain an optimized collection of SRAFs in the simulated mask. For example, such continuous variables can be treated as floating-point values and have a comparatively large number of decimal places (e.g., 3, 5, 7, etc.) to describe the optimized widths. Such implementations can thus have the technical advantage of providing highly optimized mask patterns.

Such implementations can be incorporated into a mask optimization process that may include, for example, simulating a lithography process utilizing a lithography model, predicting an imaging characteristic of the mask as simulated by the lithography model, and adjusting the width of one or more SRAFs to optimize the imaging characteristic by use of a cost function related to the imaging characteristic. The lithography model can include performing optical proximity correction optimization to generate boundaries of mask features that include assist features. In other embodiments, the lithography model can further include co-optimizing an illumination source in a source-mask optimization (SMO) in a lithography system along with optimizing the mask features.

While cost functions and their use in optimizing a lithography process were described above (in a general sense), in some implementations consistent with the disclosed with optimization of the SRAFs a cost function relating to the constant-width SRAFs can be utilized in the mask optimization process. The cost function can include parameters describing one or more of an edge placement error, sidelobe printing, MRC compliance, or a user-defined custom requirement, where at least one of the parameters is a function of the widths. As one example, a cost function can be a cost (S) that is a function (e.g., a sum) of cost functions for any combination of such parameters:

$$S = {S}_{E P E} ( {x}_{1} ) + {S}_{s i d e l o b e} ( {x}_{2} ) + {S}_{M R C} ( {x}_{3} ) + {S}_{c u s t o m} ( {x}_{4} ) + … . \qquad ( Eq . 1 )$$

In Eq. 1, the “x” variable can comprise any appropriate dependencies for the calculated cost function, and as noted above, can include the SRAF width such that the cost is a function of one or more computed SRAF widths. Such dependency can be explicit (i.e., having the width variable directly in the calculation) or implicit (i.e., based on a quantity that changes due to a variation in width, such as an amount of sidelobe printing). Also, not all of the terms above need depend on width and any combination of width-dependent or width-independent expressions are contemplated.

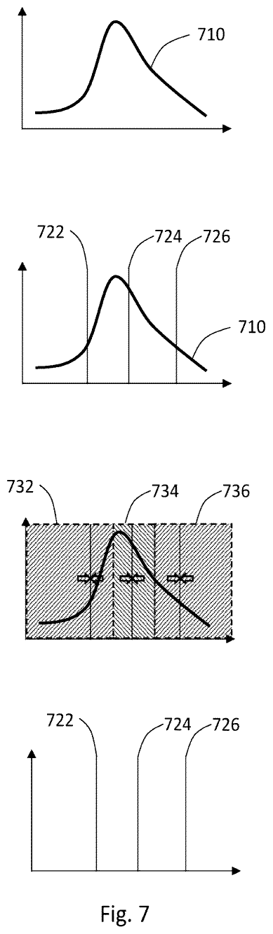

FIG. 7 illustrates an exemplary method of discretizing SRAF widths. The depicted method represents the ability of some disclosed embodiments to determine selected widths for the SRAFs. The determination may be based on statistics of the resultant widths of the SRAFs from the optimization process presented above. In various embodiments, rather than each SRAF having its own individual width, there can be a specific number of widths that the SRAFs may be, each with having its own distinct value. In some embodiments, the number of selected widths can be less than five, but may also be, for example, less than 10, less than 4, or exactly 2, 3, 5, 10, etc. One exemplary method where there are three widths is depicted in FIG. 7 by the four graphics where a large population of varying widths are adjusted to be one of three widths.

The top portion of FIG. 7 illustrates that the method can include determining a population 710 or a population distribution of the optimized widths. The population is represented by a curve with the width of an SRAF on the horizontal axis and the number of SRAFs at the width given by the vertical axis. As there may be tens or even hundreds of SRAFs each having their own widths, the “population” of such can be represented by a histogram having arbitrary, but generally fine-scale, binning. Again, the depicted graphic does not require that a curve representing such a histogram can be generated by the system but rather only that the population of SRAFs at particular widths are quantified.

The second portion of FIG. 7 illustrates three exemplary widths within the range of widths covered by the population of SRAFs. Here, the method can include setting the selected widths (e.g., widths 722, 724, 726) within a range of widths of the population based on one or more rules. In some embodiments, the rules can include setting the selected widths evenly within the range of widths such that the values of the widths are evenly separated, or such that there are an even (same) number of SRAFs at each of the widths.

The third portion of FIG. 7 illustrates that the system can set the width of each SRAF to the nearest selected width. This is illustrated by the population being broken into three regions (732, 734, 736) (depicted by the differing cross hatches) where the boundary between each region is selected to be midway between adjacent selected widths (e.g., the boundary between regions 732 and 734 is between selected widths 722 and 724). The arrows illustrate that the previously varying widths can then be changed or collapsed into the selected width in that region.

The fourth (bottom) portion of FIG. 7 then illustrates the final distribution of widths where all of the SRAFs now have widths corresponding to selected widths 722, 724, or 726. While the actual population may be the same in each width, depending on the method of region determination, there may be different numbers of SRAFs having the selected widths. The depicted final result has a number of technical advantages including being a substantially optimized solution but providing a mask pattern that utilizes a reduced number of widths. Such condensing of SRAF widths can thereby simplify (or meet) manufacturing requirements (where a vast number of SRAF widths may be impractical) while substantially maintaining the benefit of having SRAF widths that were determined by a highly precise optimization. Also, in some embodiments, there can be yet further optimizations that occur to arrive at the final widths.

In other embodiments, rather than the widths of the SRAFs being continuous variables that can be optimized, the width of each SRAF can be a discrete variable that can be optimized by the further mask optimization process. Thus, in such implementations, there can be fewer discrete variables than SRAFs. For example, there may be three discrete values for possible widths of the numerous SRAFs. In some embodiments, the system can define “global width levels” as widths selected from a group of widths that SRAFs are permissible during optimization. Thus, in certain embodiments, each discrete variable can correspond to a global width level. An example of the relationship between permissible SRAFs widths, global width levels, and their representation by a discrete variable is depicted in the table below:

| Permissible Widths | Global Width Level | Discrete variable |
|---|---|---|
| 1.0 nm | 1.0 nm | a |
| 2.0 nm | | |
| 4.0 nm | 4.0 nm | b |
| 5.7 nm | 5.7 nm | c |
| 8.0 nm | | |
| 8.2 nm | | |
| 9.0 nm | | |

Referring back to the use of cost functions to perform the mask optimization, a simplified expression of such a cost function (having cost “S,” to be minimized) that utilizes widths restricted to particular global width levels, but may be varied to be any combination of such, is shown in Eq. 2, below:

$$S = C F ( {w}_{i} ( {x}_{a , b , or c} ) ) . \qquad ( Eq . 2 )$$

In various embodiments, the global width levels can be fixed or optimized during the mask optimization process. For example, in embodiments that include fixing the global width levels during the mask optimization process, other parameters that affect the cost function can be varied while holding the global width levels at their selected values (e.g., 1.0 nm, 4.0 nm, and 5.7 nm from the above example table). In other embodiments, the method can include optimizing the global width levels during the mask optimization process. For example, a constraint of the system can be that there are only three discrete width levels but those three width levels can be optimized over a continuous range. Thus, for example, the system may determine that widths of 1.2, 4.37, and 6.245 are the optimized global width levels for the SRAFs. In another embodiment, the optimization can include selecting the global width levels from the permissible widths such that the use of those global width levels by the SRAFs result in an optimized solution. For example, the final cost of a particular solution where the global width levels are 1.0 nm, 4.0 nm, and 5.7 nm may be higher (less optimal) than the final cost of a particular solution where the global width levels are 2.0 nm, 4.0 nm, and 8.2 nm. Thus, the optimized solution would use the latter set of global width levels for SRAFs in the mask pattern.

FIG. 8 illustrates a combined optimization method including optimizing widths as both continuous and discrete values in different parts of the optimization process. As shown in FIG. 8, the step (540) of adjusting the width of the SRAFs can include additional operations (810-830) described below. Operation 810 can include determining continuous widths of the SRAFs. This operation can be similar to that depicted in the top portion of FIG. 7 where the SRAF widths can be optimized continuously. Operation 820 can include discretizing the continuous widths of the SRAFs into discrete widths. This operation can also be similar to those depicted in the second through fourth portions of FIG. 7 where, via the any of the disclosed algorithms, the previously determined continuous widths are transformed into one of the specified discrete widths. These additional operations can continue at 830 by continuing the mask optimization process by varying the widths to be selected from the discrete widths. One example of such was previously described with reference to Eq. 1, where once discrete widths are determined, the optimization process can determine the best combination of SRAF widths from the discrete widths.

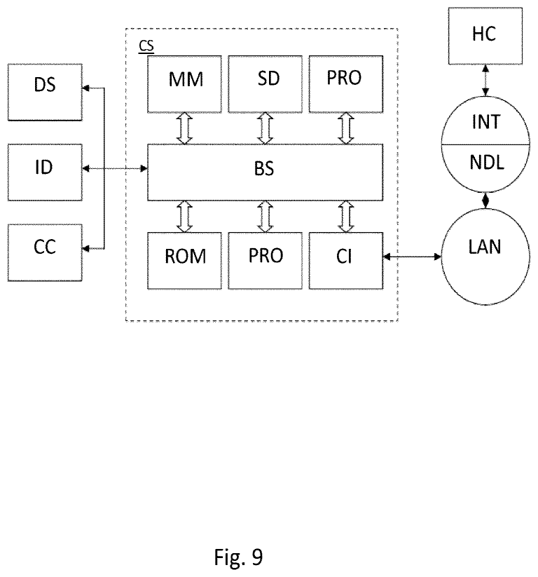

FIG. 9 is a block diagram of an example computer system CS, according to an embodiment.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

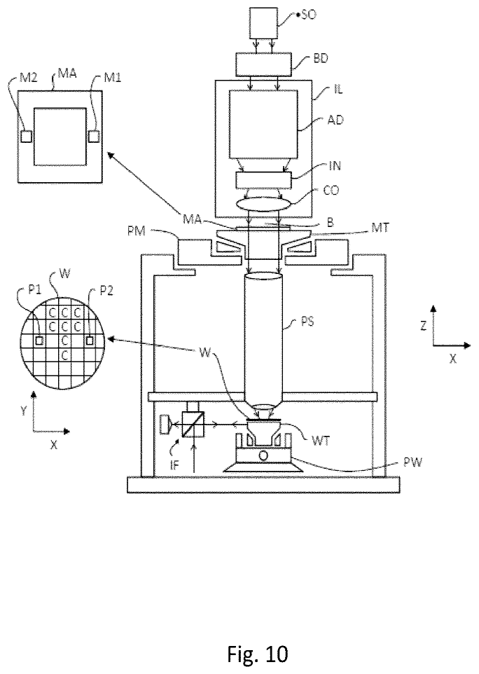

FIG. 10 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as a-outer and a-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g. so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

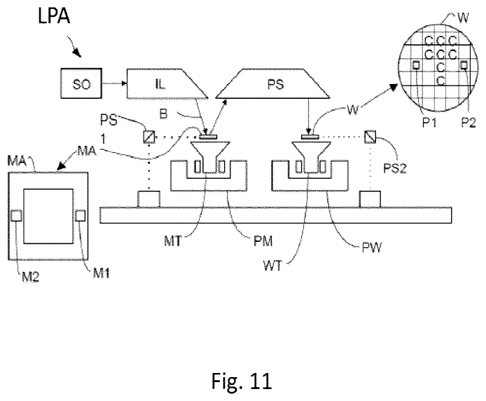

FIG. 11 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and c-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

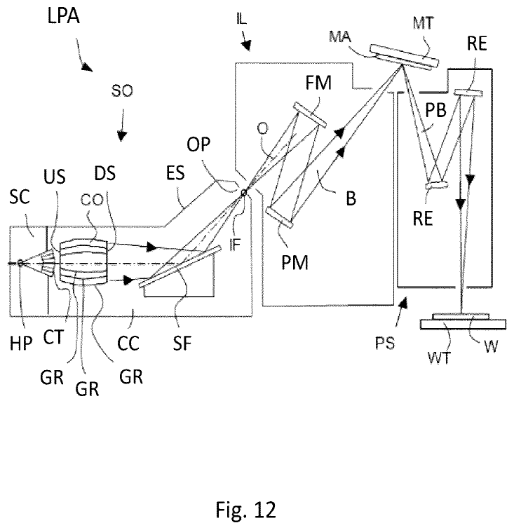

FIG. 12 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device pm arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

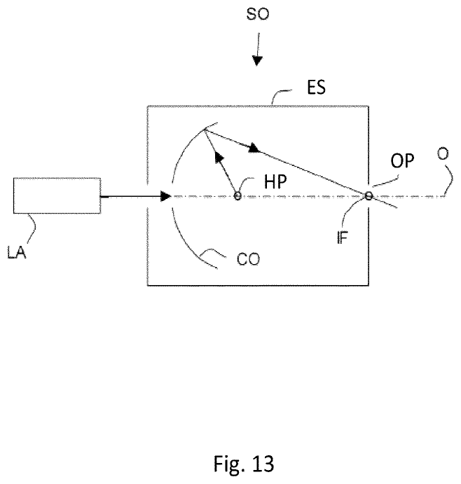

FIG. 13 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Embodiments of the present disclosure can be further described by the following clauses.

1. A method of determining mask patterns, the method comprising:
obtaining a mask pattern comprising sub-resolution assist features (SRAFs) each having constant widths; and
adjusting the widths during a mask optimization process of the mask pattern.
   2. The method of clause 1, further comprising:
accessing initial discrete width levels defined for the SRAFs; and
assigning the widths to be initial widths from the initial discrete width levels.
   3. The method of clause 1, further comprising generating SRAF edges.
   4. The method of clause 3, further comprising generating the SRAF edges to be at approximately equal distances from ridge points corresponding to a location of the SRAF.
   5. The method of clause 4, wherein the generated SRAF edges are curved.
   6. The method of clause 4, wherein the ridge points are determined such that the SRAF edges are smoothly varying.
   7. The method of clause 4, further comprising determining ridge points from an SRAF Guidance Map (SGM), the ridge points located between the corresponding SRAF edges.
   8. The method of clause 7, the generating of the SRAF edges comprising: performing interpolation over at least two ridge points when a distance between two ridge points exceeds a distance limit, the interpolation generating an interpolated ridge point.
   9. The method of clause 8, wherein the interpolated ridge point is generated at a midpoint of a segment between two ridge points.
   10. The method of clause 8, wherein the interpolated ridge point is generated along a spline interpolated curve between the two ridge points and the spline interpolated curve is generated utilizing at least one other ridge point.
   11. The method of clause 3, the generating of the SRAF edges comprising: generating control points at both ends of segments normal to the ridge points of the SRAF, wherein the segments have a length corresponding to the constant width of the SRAF.
   12. The method of clause 3, further comprising appending tips to the SRAF edges.
   13. The method of clause 1, wherein the width of each SRAF is set as a continuous variable that is optimized by the mask optimization process.
   14. The method of clause 13, the mask optimization process comprising:
simulating a lithography process utilizing a lithography model;
predicting an imaging characteristic of the mask as simulated by the lithography model; and
adjusting the width of one or more SRAFs to optimize the imaging characteristic by use of a cost function related to the imaging characteristic.
   15. The method of clause 14, further comprising performing optical proximity correction optimization to generate boundaries of mask features that include assist features (AFs).
   16. The method of clause 15, further comprising co-optimizing an illumination source in a source-mask optimization (SMO) in a lithography system along with optimizing the mask features.
   17. The method of clause 1, wherein a cost function utilized in the mask optimization process comprises parameters describing one or more of an edge placement error, sidelobe printing, mask rule check (MRC) compliance, or a user-defined custom requirement, and wherein at least one of the parameters is a function of the widths.
   18. The method of clause 1, further comprising determining selected widths for the SRAFs based on optimized continuous variables of width.
   19. The method of clause 18, wherein the number of selected widths is less than five.
   20. The method of clause 18, the determining further comprising:
determining a population or a population distribution of the optimized widths;
setting the selected widths within a range of widths of the population or population distribution based on one or more rules; and
setting the width of each SRAF to the nearest selected width.
   21. The method of clause 20, wherein the one or more rules includes setting the selected widths evenly within the range of widths.
   22. The method of clause 1, wherein the width of each SRAF is a discrete variable that is optimized by the further mask optimization process, and wherein there are fewer discrete variables than SRAFs.
   23. The method of clause 22, wherein each discrete variable corresponds to a global width level.
   24. The method of clause 23, further comprising fixing the global width levels during the mask optimization process.
   25. The method of clause 23, further comprising optimizing the global width levels during the mask optimization process.
   26. The method of clause 1, the adjusting of the widths comprising:
determining continuous widths of the SRAFs as continuous variables;
discretizing the continuous widths of the SRAFs into discrete widths; and
continuing the mask optimization process by varying the widths to be selected from the discrete widths.
   27. A non-transitory computer readable medium having instructions recorded thereon, the instructions when executed by one or more programmable processors cause the processors to perform a method of any of the clauses 1-26.
   28. A system for determining mask patterns, the system comprising:
at least one programmable processor; and a non-transitory computer readable medium having instructions recorded thereon, the instructions when executed by the at least one programmable processors cause the system to perform a method of any of the clauses 1-26.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A method for of determining mask patterns, the method comprising:
obtaining a mask pattern comprising sub-resolution assist features (SRAFs), each SRAF having constant widths; and
adjusting, by a hardware computer, the widths of the SRAFs during a mask optimization process of the mask pattern.

2. The method of claim 1, further comprising:
accessing initial discrete width levels defined for the SRAFs; and
assigning the widths to be initial widths from the initial discrete width levels.

3. The method of claim 1, further comprising generating SRAF edges to be at approximately equal distances from ridge points corresponding to a location of the SRAF, wherein the generated SRAF edges are curved, and wherein the ridge points are determined such that the SRAF edges are smoothly varying.

4. The method of claim 3, further comprising determining ridge points from an SRAF guidance map (SGM), and performing interpolation over at least two ridge points when a distance between two ridge points exceeds a distance limit, the interpolation generating an interpolated ridge point.

5. The method of claim 3, wherein the generating of the SRAF edges comprises generating control points at both ends of segments normal to the ridge points of the SRAF, wherein the segments have a length corresponding to the constant width of the SRAF.

6. The method of claim 1, wherein the width of each SRAF is set as a continuous variable that is optimized by the mask optimization process.

7. The method of claim 6, wherein the mask optimization process comprises:
simulating a lithography process utilizing a lithography model;
predicting an imaging characteristic of the mask as simulated by the lithography model; and
adjusting the width of one or more SRAFs to optimize the imaging characteristic by use of a cost function related to the imaging characteristic.

8. The method of claim 1, further comprising performing optical proximity correction optimization to generate boundaries of mask features that include assist features (AFs), or co-optimizing an illumination in a source-mask optimization (SMO) in a lithography system along with optimizing the mask features.

9. The method of claim 1, wherein a cost function utilized in the mask optimization process comprises one or more parameters describing one or more of selected from: edge placement error, sidelobe printing, mask rule check (MRC) compliance, or a predefined requirement, and wherein at least one of the one or more parameters is a function of the widths.

10. The method of claim 8, further comprising determining selected widths for the SRAFs based on optimized continuous variables representing widths.

11. The method of claim 10, wherein the determining comprises:
determining a population or a population distribution of the optimized widths;
setting the selected widths within a range of widths of the population or population distribution based on one or more rules; and
setting the width of each SRAF to the nearest selected width.

12. The method of claim 1, wherein the width of each SRAF is a discrete variable that is optimized by the mask optimization process, and wherein there are fewer discrete variables than SRAFs, wherein each discrete variable in the mask optimization process corresponds to a global width level.

13. The method of claim 12, further comprising fixing or optimizing the global width levels during the mask optimization process.

14. The method of claim 1, wherein the adjusting of the widths comprises:
determining continuous widths of the SRAFs as continuous variables;
discretizing the continuous widths of the SRAFs into discrete widths; and
performing the mask optimization process by varying the widths to be selected from the discrete widths.

15. A non-transitory computer readable medium having instructions recorded thereon or therein, the instructions, when executed by at least one programmable processor, configured to cause the at least one programmable processor to at least:
obtain a mask pattern comprising sub-resolution assist features (SRAFs), each SRAF having constant widths; and
adjust the widths of the SRAFs during a mask optimization process of the mask pattern.

16. The medium of claim 15, wherein the instructions are further configured to cause the at least one programmable processor to:
access initial discrete width levels defined for the SRAFs; and
assign the widths to be initial widths from the initial discrete width levels.

17. The medium of claim 15, wherein the instructions are further configured to cause the at least one programmable processor to generate SRAF edges to be at approximately equal distances from ridge points corresponding to a location of the SRAF, wherein the generated SRAF edges are curved, and wherein the ridge points are determined such that the SRAF edges are smoothly varying.

18. The medium of claim 15, wherein the width of each SRAF is set as a continuous variable that is optimized by the mask optimization process.

19. The medium of claim 15, wherein the instructions are further configured to cause the at least one programmable processor to perform optical proximity correction optimization to generate boundaries of mask features that include assist features (AFs), or co-optimize an illumination in a source-mask optimization (SMO) in a lithography system along with optimizing the mask features.

20. The medium of claim 15, wherein a cost function utilized in the mask optimization process comprises one or more parameters describing one or more of selected from: an edge placement error, sidelobe printing, mask rule check (MRC) compliance, or a predefined requirement, and wherein at least one of the one or more parameters is a function of the widths.
